(19) United States
(12) Patent Application Publication
(10) Pub. No.: US 2024/0329213 A1
(43) Pub. Date: Oct. 3, 2024

(54) SRAM BASED EVENT DRIVEN COMPACT HISTOGRAM ON PIXEL DIRECT TIME OF FLIGHT

(71) Applicant: Meta Platforms Technologies, LLC, Menlo Park, CA (US)

(72) Inventors: Ali Mesgarani, Sunnyvale, CA (US); Augusto Ronchini Ximenes, Seattle, WA (US); Nishit Sumanbhai Patel, San Jose, CA (US)

(21) Appl. No.: 18/190,853

(22) Filed: Mar. 27, 2023

(51) Int. Cl. G01S 7/4865; G01S 7/4863

(52) U.S. Cl. CPC G01S 7/4865; G01S 7/4863; G11C 11/419; H01L 25/167

(57) ABSTRACT

In one embodiment, a system may comprise a plurality of photon sensors for detecting photons, a plurality of event registers for storing photon-detection events detected by the plurality of photon sensors during an exposure window after a laser event, and an SRAM disposed under the plurality of photon sensors. The SRAM may comprise a plurality of memory cells associated with each photon sensor of the plurality of photon sensors to store a histogram of photon-detection events. Each memory cell may store photon-detection events detected during a predetermined time period after the laser event. The SRAM may comprise an in-memory incrementor to update the plurality of memory cells based on the photon-detection events. The in-memory incrementor may read an event count stored in a selected one of the plurality of memory cells, increment the event count, and write the incremented event count back to the selected memory cell.

### TECHNICAL FIELD

This disclosure generally relates to a time of flight sensor for depth measurements.

### BACKGROUND

Artificial reality is a form of reality that has been adjusted in some manner before presentation to a user, which may include, e.g., a virtual reality (VR), an augmented reality (AR), a mixed reality (MR), an extended reality (ER), a hybrid reality, or some combination and/or derivatives thereof. Depth sensors may allow users at different locations to capture depth information of a scene from artificial reality content in AR/VR systems. For example, Direct Time of Flight (DToF) depth sensors are usually implemented using single photon avalanche diode (SPAD) pixel array and time to digital converter based receiver architectures. The SPAD pixel array can be used in a sensitive photodetector whose high gain arises from avalanching within a photodiode. Likewise, DToF depth sensors can implement one or more groups of SPAD pixel arrays in a single silicon substrate using complementary metal-oxide semiconductor (CMOS) technologies to detect single photons during an exposure window after a laser event by counting the occurrence of short duration trigger pulses, such as photon-detection events, triggered by the detected photons during a predetermined time period after the laser event. As a result, DToF depth sensor can measure a time period from the irradiation time moment of the laser event, such as a laser diode (LD) pulse, to the time moment corresponding to the output pulse, such as the photon-detection events, of the SPAD pixel array.

Artificial reality content may include completely generated content or generated content combined with captured content (e.g., real-world photographs). The artificial reality content may include video, audio, haptic feedback, or some combination thereof, and any of which may be presented in a single channel or in multiple channels (such as stereo video that produces a three-dimensional effect to the viewer). Artificial reality may be associated with applications, products, accessories, services, or some combination thereof, that are, e.g., used to create content in an artificial reality and/or used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers. In particular, the AR/VR systems can determine the depth information of the scene to generate one or more models, such as a point cloud, a mesh, a contour map, or a 3D object model, for one or more objects, such as an object or person, in the scene or for the whole scene for the users.

### SUMMARY OF PARTICULAR EMBODIMENTS

Particular embodiments described herein relate to systems and methods of a static random access memory (SRAM) based accumulation and storage approach to use high density SRAM cells in a compact area to fit the accumulation under an SPAD pixel array for AR/VR systems. In particular, the AR/VR systems can apply the SRAM based accumulation and storage approach in a plurality of photon sensors in a depth sensing system for detecting photons during an exposure window after a laser event. For example, the depth sensing system can be a histogram on pixel DTOF depth sensor which implements one or more groups of SPAD pixel arrays to measure a time period from the irradiation time moment of the laser event to the time moment corresponding to the output pulse of the SPAD pixel array associated with photon-detection events associated with the laser event. The depth sensing system can include a plurality of event registers configured to store the photon-detection events detected by the plurality of photon sensors during the exposure window. The histogram on pixel DTOF depth sensor can provide significant power saving and high frame rates compared to traditional time to digital converter (TDC) based depth sensors. For example, the histogram on pixel DToF depth sensor can use high density SRAM cells under the SPAD pixel array to make it feasible to fit the counters for histogram bins under the SPAD pixel array when the SPAD pitch is very small. Thus, the histogram on pixel DTOF depth sensor can provide an improved spatial resolution to detect small SPAD pitch by generating a high quality histogram using dense density SRAM cells.

In an embodiment, the depth sensing system is programmed to include an SRAM disposed under the plurality of photon sensors. In particular, the SRAM may comprise a plurality of memory cells associated with cach photon sensor of the plurality of photon sensors. The plurality of memory cells is configured to store a histogram of photon-detection events detected by the associated photon sensor during the exposure window. Each memory cell of the plurality of memory cells is configured to store the photon-detection events detected during a predetermined time period after the laser event. In particular, the plurality of memory cells and the in-memory incrementor are coupled to a row decoder and a column decoder to decode a row address and a column address for each of the plurality of memory cells associated with each photon sensor of the plurality of photon sensors. In particular, the SRAM disposed under the plurality of photon sensors comprises 128 memory cells associated with each photon sensor of the plurality of photon sensors.

In an embodiment, the SRAM may comprise an in-memory incrementor which is configured to update the plurality of memory cells based on the photon-detection events stored by the plurality of event registers. In particular, a quenching transistor, an event synchronizer, an OR tree, and a global synchronous clock that re-times all input logic are coupled to the plurality of memory cells to generate a plurality signals for laser event time, precharge time, row address time, sense time, and write time. The SRAM disposed under the plurality of photon sensors may include a plurality of bitlines. Each of the plurality of bitlines is coupled to a corresponding one of the plurality of memory cells. Thus, the SRAM disposed under the plurality of photon sensors may include a precharge circuit configured to determine a precharge time for the plurality of bitlines using the precharge time signal and the row address time signal.

Furthermore, the SRAM disposed under the plurality of photon sensors may include a bit line settling circuit configured to determine a bit line settling time for the plurality of bitlines using the row address time signal and the sense time signal. The SRAM disposed under the plurality of photon sensors may include a sense amplitude and incrementor delay circuit configured to determine a sense amplitude and incrementor delay time for the plurality of bitlines using the sense time signal and the write time signal. The SRAM disposed under the plurality of photon sensors may include a write delay circuit configured to determine a write delay time for the plurality of bitlines using the row address time signal and the write time signal. For each of the photon-detection events stored in the plurality of event registers, the in-memory incrementor is configured to read an event count stored in a selected one of the plurality of memory cells, increment the event count, and write the incremented event count back to the selected memory cell. For example, the SRAM disposed under the plurality of photon sensors performs one or more operations on SRAM values for the plurality of memory cells using the event count stored in the plurality of memory cells. The one or more operations include a read operation, a write operation, a fresh operation, and an update operation based on row/column address for each of the plurality of memory cells. As a result, the SRAM disposed under the plurality of photon sensors can determine a direct time to flight using a time to digital converter based on the high quality histogram of photon-detection events detected by the associated photon sensor during the exposure window.

The embodiments disclosed herein are only examples, and the scope of this disclosure is not limited to them. Particular embodiments may include all, some, or none of the components, elements, features, functions, operations, or steps of the embodiments disclosed herein. Embodiments according to the invention are in particular disclosed in the attached claims directed to a method, a storage medium, a system and a computer program product, wherein any feature mentioned in one claim category, e.g. method, can be claimed in another claim category, e.g. system, as well. The dependencies or references back in the attached claims are chosen for formal reasons only. However any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein cach feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

### BRIEF DESCRIPTION OF THE DRAWINGS

FIG. 1A illustrates an example artificial reality system.

FIG. 1B illustrates an example augmented reality system.

FIG. 2 illustrates an example histogram on pixel (HoP) direct time of flight (DToF) depth sensor 200 of the AR/VR systems.

FIG. 3 illustrates an example system 300 which includes a readout integrated circuit (ROIC) 220 and a time to digital converter (TDC) 230 associated with the histogram on pixel DToF depth sensor.

FIG. 4 illustrates an example powered device integrated circuit (PDIC) 400.

FIG. 5 illustrates an example SRAM unit cell 500 with 128 histogram bins.

FIG. 6 illustrates an example circuitry 600 of a histogram bin.

FIGS. 7A and 7B illustrate example circuitries of accumulation and memory in a compact SRAM unit cell with event register without event register.

FIGS. 8A, 8B, and 8C illustrate example multiple time signals to capture a laser event.

FIG. 9 illustrates an example method 900 for performing a method to generate a histogram of photon-detection events using a plurality of photon sensors.

FIG. 10 illustrates an example computer system.

### DESCRIPTION OF EXAMPLE EMBODIMENTS

A histogram on pixel DToF depth sensor is important tool to accurately look for advanced human-machine interaction interfaces, such as gesture recognition, motion tracking, etc. The histogram on pixel DTOF depth sensor usually implement SPAD sensor and time to digital converter (TDC) based receiver architectures. The AR/VR systems can use cameras equipped with one or more histogram on pixel DToF depth sensors to accurately capture depth information of a scene of the AR/VR systems and generate a three-dimensional (3D) geometric model for an object or a person in the scene. Traditional dense sensors suffer from the limitations of low resolution, short sensing distance, and sensitivity of optical interference. It is very challenging to use tradition dense sensors to track the viewpoint of a user, such as a head position, eye positions, a center position of two eyes of the user. The SPAD sensor is an image sensor which can capture a very high resolution in low light environment as the SPAD sensor can measure a time of flight (TOF) of a light pulse using an external single-photon avalanche diode pixel array and a histogram-based time to digital converter (TDC) array due to the high speed that the avalanche builds up and the low timing jitter of the SPAD sensor. In particular, the SPAD sensor can detect single photons during an exposure window after a laser event providing short duration trigger pulses, such as photon-detection events, that can be counted.

In particular, the SPAD pixel array can apply a static random access memory (SRAM) based accumulation and storage approach that takes advantage of compact SRAM area to fit the accumulation under the SPAD pixel array. In applications, where an SPAD pitch is very small, it is not feasible to fit the counters for histogram bins under the SPAD pixel arrays. In these situations, either the counter depth or the number of histogram bins have to be sacrificed which results in degraded performance of the depth sensor for either lower signal to noise ratio (SNR) or a lower spatial resolution. To solving these challenges, instead of using large registers as accumulator, the histogram on pixel DTOF depth sensor can use high density SRAM unit cells under the SPAD pixel array and only update the SRAM values when there is an event sensed for a high quality histogram of photon-detection events detected by the associated depth sensor during the exposure window. For example, the SPAD sensor can measure each individual light particle, such as photon, that reaches a pixel. Each photon that enters the pixel immediately gets converted into an electric charge, and the electrons that result are eventually multiplied like an avalanche until they form a large signal charge that can be extracted. Each SRAM unit cell can include an in-memory incrementor configured to update the plurality of memory cells based on the photon-detection events stored by a plurality of event registers. Each of the photon-detection events stored in the plurality of event registers. The in-memory incrementor is configured to read an event count stored in a selected one of the plurality of memory cells, increment the event count, and write the incremented event count back to the selected memory cell. Because the SPAD sensor can accurately detect photon entry across the entire range of effective pixels, more accurate information can be received per photon due to multiplication. Under equivalent light, the SPAD sensor can capture the same images as a traditional depth sensor while requiring only a small portion of imaging area. The SPAD sensor is well suited to be installed in a compact area under a powered device integrated circuit (PDIC) for one or more cameras of the AR/VR systems. As a result, the histogram on pixel DTOF sensors provide high sensitivity, high resolution, and high-speed response to monitor video footage of fast moving objects in low-light environments as if the objects are recorded in bright areas, enabling identification of subject movement as though viewing with naked eyes in well-lit environments. Furthermore, the histogram on pixel DToF sensors can offer significant power saving and higher frame rates compared to TDC based approaches by accumulating histogram in counters placed under the SPAD pixel arrays.

In particular embodiments, the AR/VR systems may include an authorization server (or other suitable component(s)) that allows users to opt in to or opt out of having their actions logged by the AR/VR systems or shared with other systems (e.g., third-party systems), for example, by setting appropriate privacy settings. A privacy setting of a user may determine what information associated with the user may be logged, how information associated with the user may be logged, when information associated with the user may be logged, who may log information associated with the user, whom information associated with the user may be shared with, and for what purposes information associated with the user may be logged or shared. Authorization servers may be used to enforce one or more privacy settings of the users of the AR/VR systems through blocking, data hashing, anonymization, or other suitable techniques as appropriate.

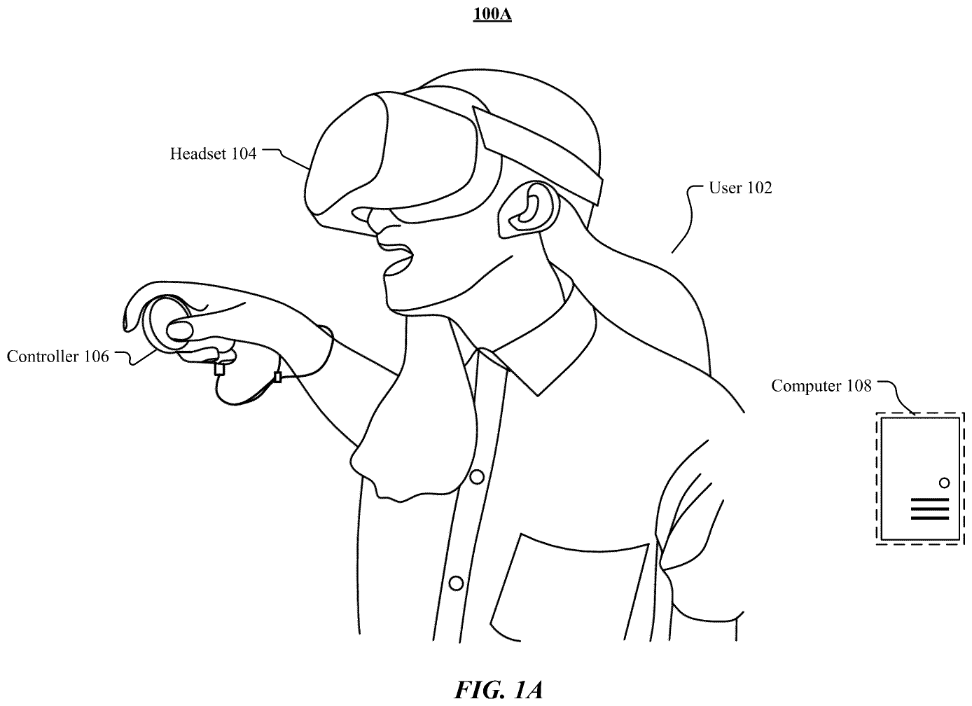

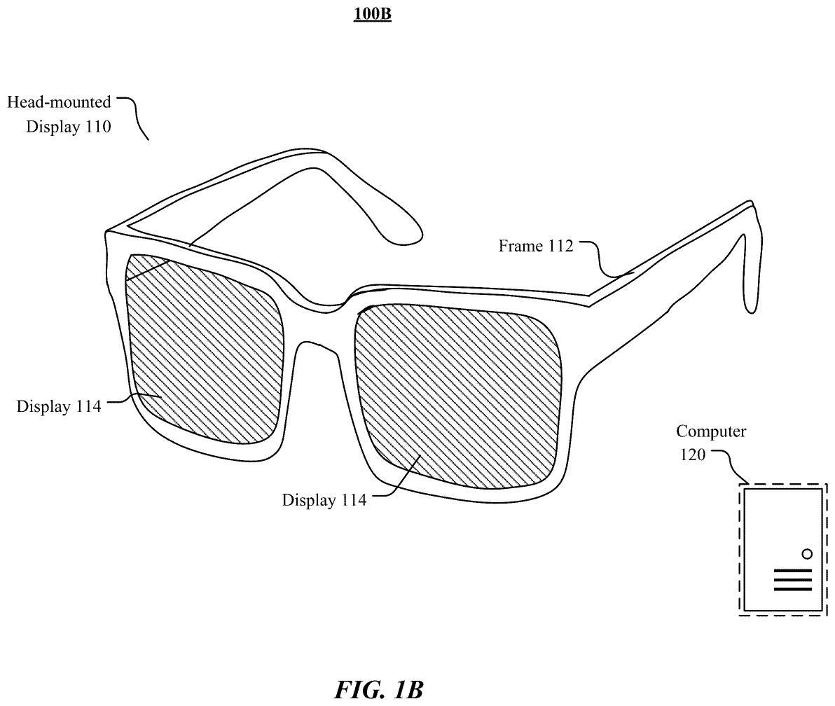

FIG. 1A illustrates an example artificial reality system 100A. In particular embodiments, the artificial reality system 100A may comprise a headset 104, a controller 106, and a computing system 108, etc. A user 102 may wear the headset 104 that could display visual artificial reality content to the user 102. The headset 104 may include an audio device that could provide audio artificial reality content to the user 102. The headset 104 may include one or more cameras which can capture images and videos of environments. The headset 104 may include an eye tracking system to determine the vergence distance of the user 102. The headset 104 may be referred as a head-mounted display (HDM). The controller 106 may comprise a trackpad and one or more buttons. The controller 106 may receive inputs from the user 102 and relay the inputs to the computing system 108. The controller 106 may also provide haptic feedback to the user 102. The computing system 108 may be connected to the headset 104 and the controller 106 through cables or wireless connections. The computing system 108 may control the headset 104 and the controller 106 to provide the artificial reality content to and receive inputs from the user 102. The computing system 108 may be a standalone host computer system, an on-board computer system integrated with the headset 104, a mobile device, or any other hardware platform capable of providing artificial reality content to and receiving inputs from the user 102.

FIG. 1B illustrates an example augmented reality system 100B. The augmented reality system 100B may include a head-mounted display (HMD) 110 (e.g., glasses) comprising a frame 112, one or more displays 114, and a computing system 120. The displays 114 may be transparent or translucent allowing a user wearing the HMD 110 to look through the displays 114 to see the real world and displaying visual artificial reality content to the user at the same time. The HMD 110 may include an audio device that may provide audio artificial reality content to users. The HMD 110 may include one or more cameras which can capture images and videos of environments. The HMD 110 may include an eye tracking system to track the vergence movement of the user wearing the HMD 110. The augmented reality system 100B may further include a controller comprising a trackpad and one or more buttons. The controller may receive inputs from users and relay the inputs to the computing system 120. The controller may also provide haptic feedback to users. The computing system 120 may be connected to the HMD 110 and the controller through cables or wireless connections. The computing system 120 may control the HMD 110 and the controller to provide the augmented reality content to and receive inputs from users. The computing system 120 may be a standalone host computer system, an on-board computer system integrated with the HMD 110, a mobile device, or any other hardware platform capable of providing artificial reality content to and receiving inputs from users.

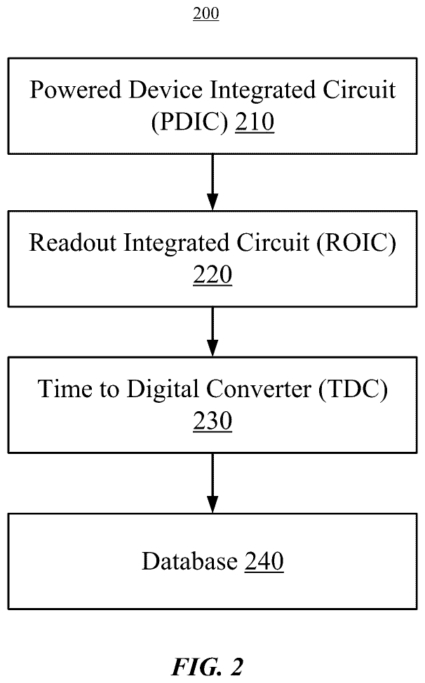

FIG. 2 illustrates an example histogram on pixel DTOF depth sensor 200 of the AR/VR systems. In particular embodiments, the histogram on pixel DToF depth sensor 200 may include a powered device integrated circuit (PDIC) 210, a readout integrated circuit (ROIC) 220, a time to digital converter (TDC) 230, and a database 240. The histogram on pixel DToF depth sensor 200 can emit individual light particle, such as photons from a laser event, and uses the PDIC 210 to receive the photon event reflected back from an object in the field of view of a user. The histogram on pixel DToF depth sensor 200 can use the ROIC 220 to assess information associated with the photon event received by the PDIC 210 in a histogram to detect the arrival time of the reflected photon event precisely. Based on when the laser is sent and the time when the reflection is captured, the AR/VR systems can accurately compute a distance between the object and the histogram on pixel DToF depth sensor 200 with a high resolution. In particular, a time counter starts counting after a laser beam is sent. When the photon event is detected, the ROIC can use the time counter to determine which histogram bin is incremented based on the detection of the photon event. Each histogram bin width corresponds to a time range, which in turn corresponds to a depth range. Usually, the count of the photon-detection events are measured in real time with some noise from ambient light being detected in addition to the laser. Therefore, the histogram on pixel DTOF depth sensor 200 can use the histograms to determine a peak associated the received photon-detection events from the object for a most likely time of flight of the laser for the object. In particular, the histogram on pixel DToF depth sensor 200 is programmed to implement a histogram via a series of flip-flop registers for each unit cell of a photon sensor, such as a unit cell of an SPAD pixel array. Each histogram bin is implemented as a series of flip-flop registers to count the number of photon-detection events occurring per bin. For example, a histogram can include 128 histogram bins in a unit cell associated with the SPAD pixel array.

In an embodiment, the histogram on pixel DTOF depth sensor 200 can use a histogram-based time to digital converter 230 coupled to an integrated histogram generation unit for a reliable TOF measurement in the depth sensors. Traditional depth sensors are deficient to generate high resolution histograms because it is difficult to fit traditional depth sensors under the PDIC without reducing bit count/resolution. The histogram on pixel DTOF depth sensor 200 can generate high resolution histograms stored in a database 240 based on a plurality of histogram bins associated with high density SRAM cells under the array. Each histogram bin in the unit cell needs a circuitry of the histogram on pixel DTOF depth sensor 200 to count the number of photon-detection events by bits detected during a time period associated with the corresponding histogram bin. For example, the time to digital converter 230 can include a 300 MHZ PLL, one or more 10-bit counters to generate 10 most significant bits (MSBs), and 2-channel 12-bit TDC cells that may include one or more registers. Each bin of the histogram can count up to 2¹⁰. As another example, the TDC cell can be designed with a compact size with a phase-dependent latching scheme to measure the time period from the irradiation time moment of the laser diode (LD) pulse to the time moment corresponding to the output pulse of the SPAD pixel array. In particular, the histogram on pixel DToF depth sensor 200 can use a large memory to generate a histogram, such as an 8 Mb memory to accumulate a 10-bit histogram for a 2-channel, 12-bit TDCs.

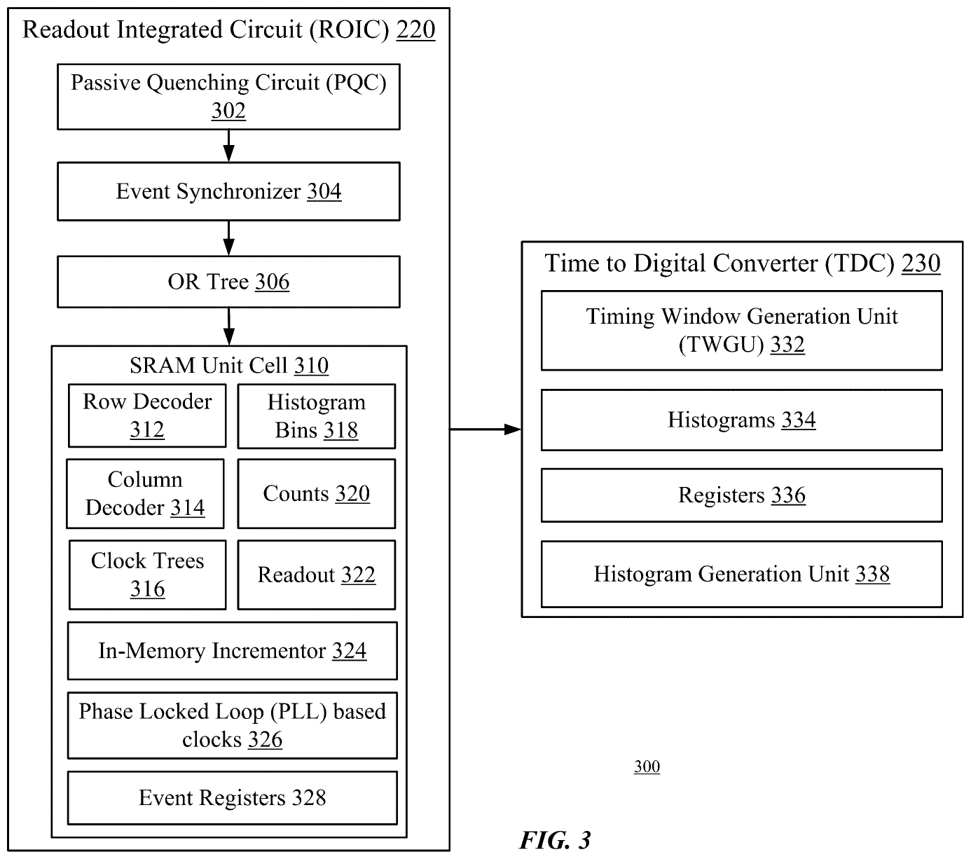

FIG. 3 illustrates an example system 300 which includes a readout integrated circuit (ROIC) 220 and a time to digital converter (TDC) 230 associated with the histogram on pixel DToF depth sensor. The ROIC 220 can be integrated in a compact area between individual SPADs associated with a plurality of sensors of the PDIC 210. For example, the ROIC 220 can use minimum sized transistors, such as passive quenching circuit (PQC) 302, to both quench the avalanche process in the photodetector and integrate charge onto a capacitor to represent the number of detected photons. After a laser is sent out, the sensors of the PDIC 210 are open during an exposure window to detect photons that bounce back from an object in the field of view of a user. The ROIC 220 can use an event synchronizer 304 to generate a logic pulse in synchronization with an optical pulse associated with the laser. As a result, the laser is coupled to the sensors of the PDIC 210. For example, the event synchronizer 304 can adjust the optical pulse width associated with the laser via a manually adjustable coupler control of the detection rate. For example, the ROIC 220 can generate a laser pulse and determine a time interval between emission of the laser pulse and its detection with a periodic generation period of 30 nanoseconds (ns). In particular, the ROIC 220 can implement OR tree 306 and phase looked loop (PLL) based clocks 326 to allow for a fine chronological extraction of the using clock trees 316 to reduce an overall circuit power consumption. The PLL based clocks 326 can be an output signal whose phase is related to the phase of an input signal to allow the ROIC 220 to synchronize the phase of its on board clock with an external timing signal.

In an embodiment, the SRAM unit cell 310 may include a plurality of memory cells associated with each photon sensor of the plurality of photon sensors, such as the SPADs. In particular, the ROIC 220 can couple the passive quenching circuit (PQC) 302, the event synchronizer 304, the OR tree 306, and a global synchronous clock that re-times all input logic, such phase lock loop (PLL) based clocks 326, to the plurality of memory cells to generate a plurality signals for laser event time, precharge time, row address time, sense time, and write time. For example, the ROIC 220 can generate four digital outputs: 1) a precharge bitline time, 2) a bit line settling time, 3) a sense amplitude and increment delay time, and 4) a write time. The four digital outputs can be used to start and stop a time measuring system, such a time to digital converter 230. In particular, the precharge bitline time characterizes a first periodic pattern for a time interval between a clock time and a row address time intended to allow dynamic circuitry of a histogram bin 318 to be charged or discharged to predetermined voltage levels prior to the start of a new cycle. The bit line settling time characterizes a second periodic pattern for a time interval between a row address time and a sense time intended to allow dynamic circuitry of the histogram bin 318 to read bit line settling addresses for the corresponding histogram bin 318 prior to the start of a new cycle. The sense amplitude and increment delay time characterizes a third periodic pattern for a time interval between a sense time and a write time intended to allow dynamic circuitry of the histogram bin 318 to be detect a photon event and update an SRAM value based on the selected bit line settling addresses for the corresponding histogram bin 318 prior to the start of a new cycle. Likewise, the write time characterizes a fourth periodic pattern for a time interval between a write time and the ending time of the activated row address time intended to allow dynamic circuitry of the histogram bin 318 to be write back the updated SRAM value based on the selected bit line settling addresses for the corresponding histogram bin 318 prior to the start of a new cycle.

In an embodiment, the SRAM unit cell 310 may include a precharge circuit configured to determine a precharge time for the plurality of bitlines using the precharge time signal and the row address time signal. The SRAM unit cell 310 may include a bit line settling circuit configured to determine a bit line settling time for the plurality of bitlines using the row address time signal and the sense time signal. The SRAM unit cell 310 may include a sense amplitude and incrementor delay circuit configured to determine a sense amplitude and incrementor delay time for the plurality of bitlines using the sense time signal and the write time signal. The SRAM unit cell 310 may include a write delay circuit configured to determine a write delay time for the plurality of bitlines using the row address time signal and the write time signal.

In an embodiment, the reflected photons can cause a charge/current to be generated from the PDIC 210. The ROIC 220 is programmed to use an SRAM unit cell 310 disposed under a plurality of photon sensors, such as the SPAD pixel arrays, to read the charge/current as an event that can be used to update a histogram. The SRAM unit cell 310 may include a row decoder 312, a column decoder 314, clock trees 316, a plurality of histogram bins 318, counts 320, a readout 322, and an in-memory incrementor 324. For example, The plurality of memory cells is configured to store a histogram of photon-detection events detected by the associated photon sensor during the exposure window, and each memory cell of the plurality of memory cells is configured to store photon-detection events detected during a predetermined time period after a laser event, such as a laser beam. Furthermore, the SRAM unit cell 310 may include a digital counter, such in-memory incrementor 324, configured to update the plurality of memory cells based on the photon-detection events stored by a plurality of event registers 328. For each of the photon-detection events stored in the plurality of event registers 328, the in-memory incrementor 324 is configured to read an event count stored in a selected one of the plurality of memory cells, increment the event count, and write the incremented event count back to the selected memory cell.

In an embodiment, when the laser beam is sent, the in-memory incrementor 324 can start counting. For each detected photo/current, the in-memory incrementor 324 can read a current count 320 of time counter to determine when a photon is received after the laser beam is sent. The in-memory incrementor 324 can determine which histogram bin 318 needs to be incremented by a value of 1 by counting the occurrence of the detected photon event using the row decoder 312, the column decoder 314, and the clock trees 316. The row decoder 312 and the column decoder 314 may perform a targeted read, write, refresh, or update operation. The plurality of memory cells and the in-memory incrementor 324 are coupled to the row decoder 312 and the column decoder 314 to decode a row address and a column address for each of the plurality of memory cells associated with cach photon sensor of the plurality of photon sensors. The SRAM unit cell 310 can perform one or more operations using row/column address for each of the plurality of memory cells on SRAM values for the plurality of memory cells using the event count stored in the plurality of memory cells. For example, when the read operation is activated based on the bit line settling time, the row decoder 312 and the column decoder 314 may select a row address and a column address to perform the read operation to read an SRAM value for the corresponding row address and column address. As another example, when the update operation is activated based on the sense amplitude and incrementor delay time, the row decoder 312 and the column decoder 314 may perform the update operation to increment the SRAM value by a value of 1 for the corresponding row address and column address. As another example, when the write operation is activated based on the bit line write delay time, the row decoder 312 and the column decoder 314 may perform the read operation to write back the updated SRAM value for the corresponding row address and column address. As a result, the readout 322 can transfer the counts 320 for the plurality of histogram bins 318 to the time to digital converter 230 to generate a histogram 334 associated with the laser beam for measuring an arrival time of reflected laser beam precisely using the time to digital converter 230.

In an embodiment, the time to digital converter 230 is programmed to generate a histogram based on the counts 320 for the plurality of histogram bins 318. For example, the time to digital converter 230 can include a timing window generation unit (TWGU) 332, histograms 334, registers 336, and a histogram generation unit 338 for a systems-on-a-chip (SoCs) depth sensor. For example, the registers 336 can store 10-bit MSBs from the in-memory incrementor 324 which can act as photon event accumulator and unit cell memory. The photon accumulator and unit cell memory is configured as shift register for readout operation. The timing window generation unit 338 can store a plurality of time periods which are determined by a plurality of storage locations addressed by the in-memory incrementor 324. Each storage location corresponds to a subinterval termed a period window. As another example, the histogram generation unit 338 can generate a histogram 334 based on the counts 320 for the plurality of histogram bins 318. In particular, the SRAM unit cell 310 can implement a 10 bit in-memory incrementor 324 and 128 histogram bins. Each histogram for a single SPAD pixel array requires 1280 byte of memory. The total memory footprint of the complete histogram for an array of 8×8 SPAD pixel arrays will be 81 Mb as required to accurately compute ToF in real time for high resolution, sensitivity, and high-speed response of the histogram on pixel DTOF depth sensor.

In an embodiment, the histogram on pixel DTOF depth sensor can be equipped on one or more cameras of the AR/VR systems. The outputs of pixels in the one or more cameras of the AR/VR systems provide information about pixel-specific TOF values to generate a 3D depth profile of the object in the scene. For example, the AR/VR systems may use a scannerless approach to capture the entire scene with each laser or light pulse. As another example, the AR/VR systems may use a single laser pulse to capture spatial and temporal data to record a 3D scene. Therefore, the AR/VR systems can use the acquired depth information to generate a 3D geometric model for an object or a person in the scene.

In particular embodiments, one or more of the content objects of the AR/VR systems may be associated with a privacy setting. The privacy settings (or “access settings”) for an object, such as the user information of a user, may be stored in any suitable manner, such as, for example, in association with the object, in the AR/VR systems, in another suitable manner, or any combination thereof. A privacy setting of an object may specify how the object (or particular information associated with an object) can be accessed (e.g., viewed or shared) using the AR/VR systems. Where the privacy settings for an object allow a particular user to access that object, the object may be described as being “visible” with respect to that user. As an example and not by way of limitation, a user of the AR/VR systems may specify privacy settings for a user-profile page that identify a set of users that may access the work experience information on the user-profile page, thus excluding other users from accessing the information. In particular embodiments, the privacy settings may specify a “blocked list” of users that should not be allowed to access certain information associated with the object. In other words, the blocked list may specify one or more users or entities for which an object is not visible. As an example and not by way of limitation, a user may specify a set of users that may not access the user information associated with the user, thus excluding those users from accessing the user information associated with the user (while also possibly allowing certain users not within the set of users to access the user information associated with the user). In particular embodiments, privacy settings may be associated with particular user information. Privacy settings of user information may specify how images and video associated with the user information, or content objects associated with the user information can be accessed using the AR/VR systems. As an example and not by way of limitation, the AR/VR systems may have a privacy setting specifying that the user information may only be accessed by the user in the particular conditions. In particular embodiments, privacy settings may allow users to opt in or opt out of having their actions logged by the AR/VR systems. In particular embodiments, the privacy settings associated with an object may specify any suitable granularity of permitted access or denial of access. As an example and not by way of limitation, access or denial of access may be specified for particular users (e.g., only me, my roommates, and my boss), users within a particular degrees-of-separation (e.g., friends, or friends-of-friends), user groups (e.g., the gaming club, my family), user networks (e.g., employees of particular employers, students or alumni of particular university), all users (“public”), no users (“private”), users of the AR/VR systems, particular applications (e.g., third-party applications, external websites), other suitable users or entities, or any combination thereof. Although this disclosure describes using particular privacy settings in a particular manner, this disclosure contemplates using any suitable privacy settings in any suitable manner.

In particular embodiments, the AR/VR systems may be authorization/privacy servers for enforcing privacy settings. In response to a request from a user (or other entity) for a particular object stored in a database 240, the AR/VR systems may send a request to the database 240 for the object. The request may identify the user associated with the request and may only be sent to the user if the authorization server determines that the user is authorized to access the object based on the privacy settings associated with the object. If the requesting user is not authorized to access the object, the authorization server may prevent the requested object from being retrieved from the database 296, or may prevent the requested object from being sent to the user. In the search query context, an object may only be generated as a search result if the querying user is authorized to access the object. In other words, the object must have a visibility that is visible to the querying user. If the object has a visibility that is not visible to the user, the object may be excluded from the search results. Although this disclosure describes enforcing privacy settings in a particular manner, this disclosure contemplates enforcing privacy settings in any suitable manner.

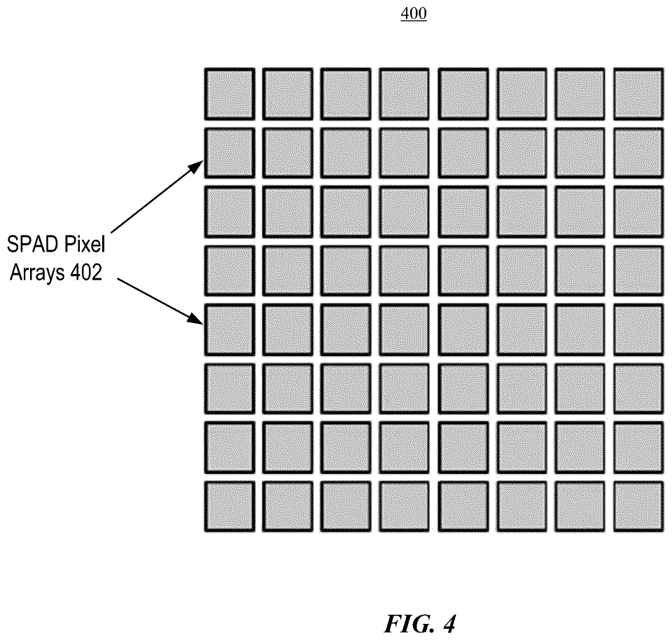

FIG. 4 illustrates an example powered device integrated circuit 400. The PDIC include 8×8 SPAD pixel arrays 402. Specifically, FIG. 4 shows 64 SPAD pixel arrays which are embedded in the PDIC 400 to receive a plurality of photons of a laser beam which is reflected off an object in the field of view of a user. Each SPAD pixel array is used in a depth sensor. For each depth sensor, an SRAM unit cell 500 is embedded underneath each depth sensor using an SRAM accumulation and storage approach in a compact SRAM area to fit the accumulation under the SPAD pixel array 402. When a photon is received by one of the SPAD pixel arrays 402, the detected photon can initiate an avalanche event in response to a received photon. The SPAD pixel arrays 402 can generate easily detected currents by biasing the avalanche diode above its breakdown voltage. Thus, a single photoelectron can give rise to self-sustaining avalanche current. Therefore, the PDIC 400 can use a plurality of dense SPAD pixel arrays in a compact area to efficiently detect photons to improve ToF measurements of the histogram on pixel DTOF depth sensors. After the photons are detected, the self-sustaining avalanche current associated with the detected photons can be actively quenched by proactively lowering an applied voltage below a breakdown voltage for halting an avalanche breakdown and priming the device ready for the next photon arrival. This sequence in an SPAD operation requires appropriate pixel-level circuitry in the ROIC 500 which adds complexity to the operation of the SPAD pixel array.

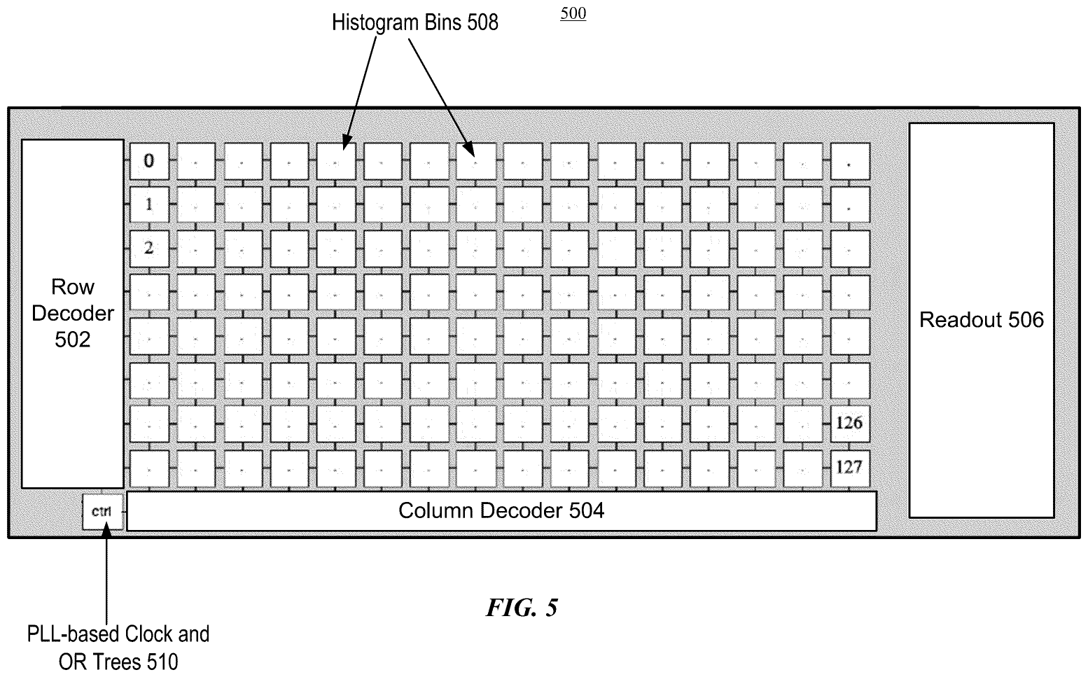

FIG. 5 illustrates an example SRAM unit cell 500 with 128 histogram bins. The SRAM unit cell 500 can include a row decoder 502, a column decoder 504, a readout 506, a plurality of histogram bins 508, and PLL-based clock and OR trees 510. The plurality of histogram bins 508 are coupled to the row decoder 502, the column decoder 504, and the PLL-based clock and OR tree to implement a read, write, update, and fresh operation associated with the plurality of histogram bins 508. The SRAM unit cell 500 can use the row decoder 502 and column decoder 504 to read addresses of a particular histogram bin 508. In particular, the SRAM unit cell 500 can include 128 histogram bins and each histogram bin width corresponds to a time range, which in turn corresponds to a depth range. For a particular histogram bin 508, the SRAM unit cell 500 can count the number of photon events detected during a time period associated with the particular histogram bin 508. For example, the SRAM unit cell 500 can implement a 10 bit digital counter as an event accumulator and unit cell memory to perform robust operations across a process, voltage, and temperature (PVT) condition. In particular, the 10 bit digital counter can be configured as a shift register to implement the readout 506 operation. As another example, the SRAM unit cell 500 can implement a histogram via a series of flip-flop registers. Each histogram bin 508 is implemented as a series of flip-flop registers to count the number of photon events occurring per bin. Under each photon sensor is an SRAM unit cell 500 that corresponds to the histogram. Because the depth sensors are small in size, it is difficult to fit histogram bins 508 under cach SPAD pixel array without reducing bit count/resolution. The SRAM unit cell 500 can implement high density histogram bins 508 and large registers, such as 9 registers, as accumulator under cach SPAD pixel array.

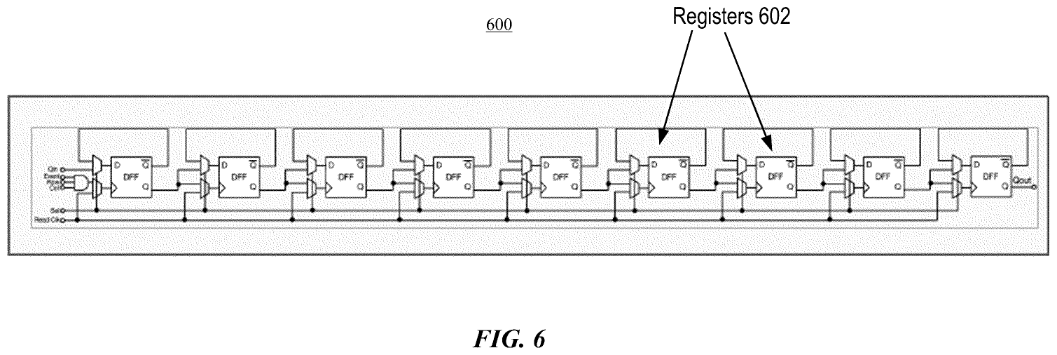

FIG. 6 illustrates an example circuitry 600 of a histogram bin. The histogram bin can include 9 registers 602 which correspond to 9 bits. Each histogram bin 508 in the SRAM unit cell 500 can count up to 2⁹. The SRAM unit cell 500 can feed data through the 9 parallel registers in a serpentine pattern. When the registers 602 are filled, the circuitry 600 can shift the parallel registers 602 to the inputs of the SRAM unit cell 500 at a speed based on a synchronized, complimentary version of a memory global clock to make sure that setup time is not violated between the breakout output and the flop inputs for a single synchronous clock that re-times all of the input logic. Therefore, the SRAM unit cell 500 can perform a read, write, update, or fresh operation to an SRAM value for a corresponding histogram bin.

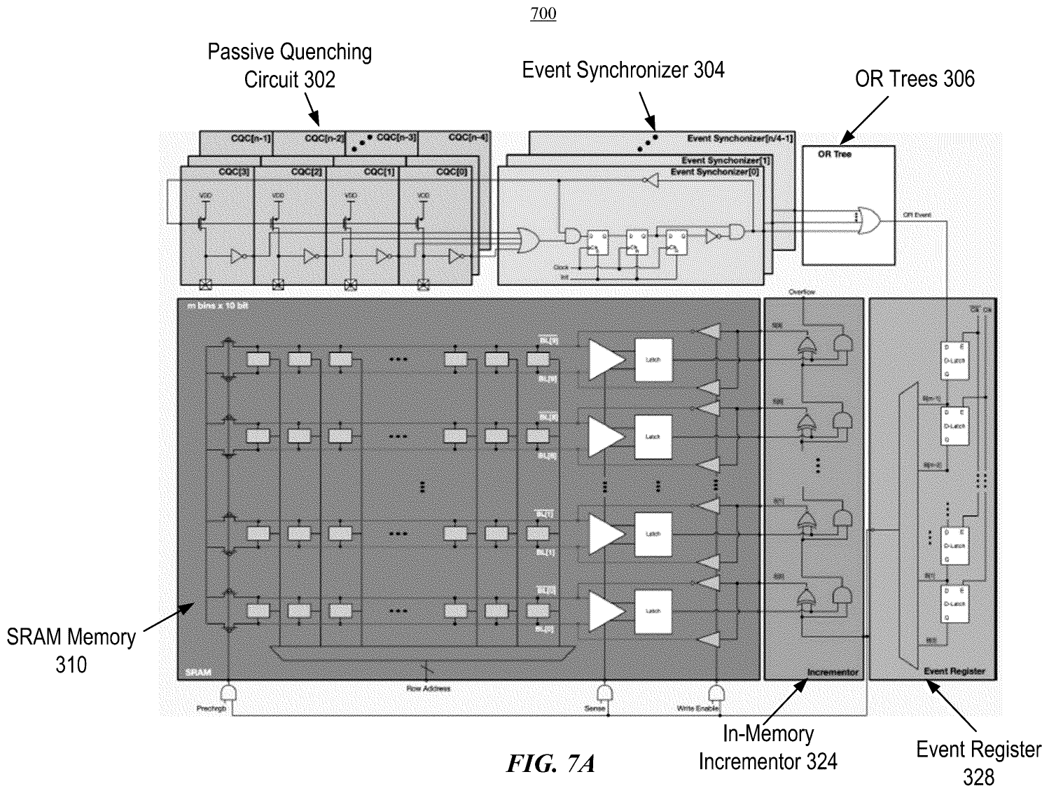

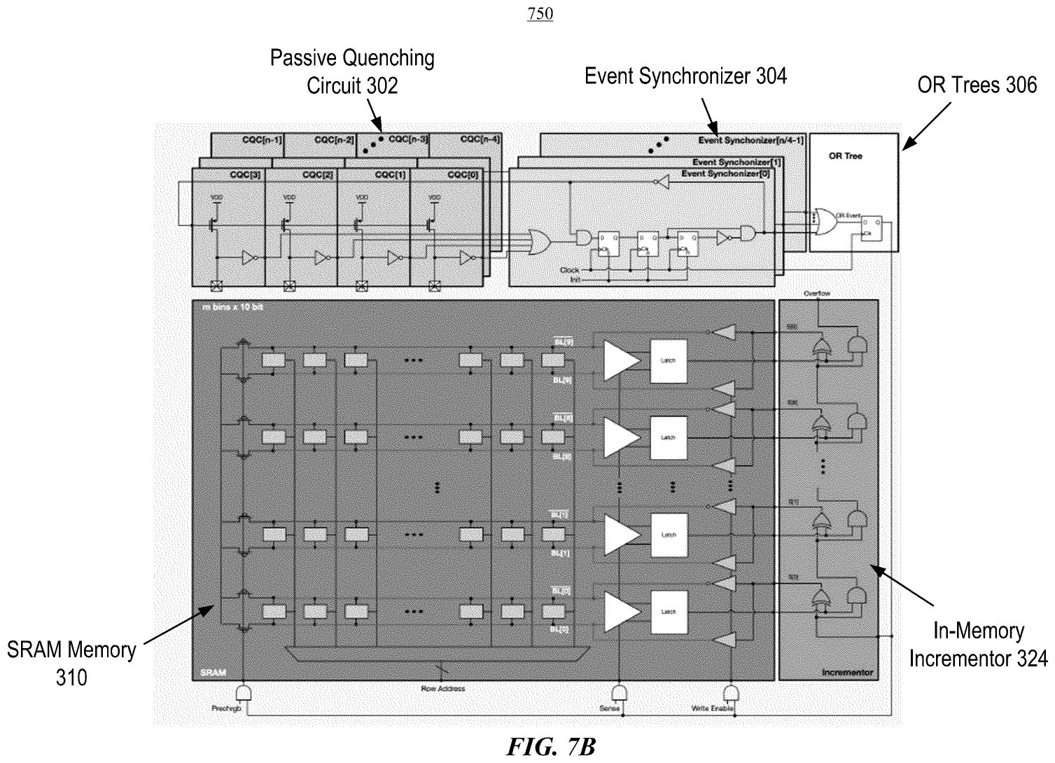

FIGS. 7A and 7B illustrate example circuitries of accumulation and memory in a compact SRAM unit cell with event register without event register. The histogram on pixel DTOF depth sensor can implement a circuitry 700 with event register 328. For example, after a laser is sent, the histogram on pixel DToF depth sensor can implement a passive quenching circuit 302, an event synchronizer 304, and OR trees 306 to detect a photon event which reflects off an object in the field of view of a user. When the SRAM pixel array is not fast enough to update as photon events come in, the SRAM memory can accumulate photon-detection events temporarily. As a result, the accumulated photon events can be processed one by one. The SRAM pixel array can couple the SRAM memory to an in-memory incrementor 324 which is configured to update the plurality of memory cells based on the photon-detection events stored by a plurality of event registers 328. The SRAM memory has an in-memory unit to perform an in-memory process of reading an SRAM value from a histogram bin, incrementing it by 1 and writing it back. All of this process is done in memory, so no power/time is wasted by reading/writing off-memory. The histogram on pixel DTOF depth sensor can count the number of photon events occurring per bin using an event register 328 which includes a series of flip-flop registers.

In an embodiment, the histogram on pixel DToF depth sensor can implement a circuitry 750 without event register in a very compact area under an SPAD sensor. For example, after a laser is sent, the histogram on pixel DTOF depth sensor can implement a passive quenching circuit 302, an event synchronizer 304, and OR trees 306 to detect a photon event which reflects off an object in the field of view of a user. When the SRAM pixel array is fast enough to update as photon events come in, the SRAM memory can perform an in-memory process of reading an SRAM value from a histogram bin, incrementing it by 1 and writing it back. All of this process is done in memory, so no power/time is wasted by reading/writing off-memory. The SRAM pixel array can couple the SRAM memory to an in-memory incrementor 324 which is configured to update the plurality of memory cells based on photon-detection events stored by a plurality of event registers 328.

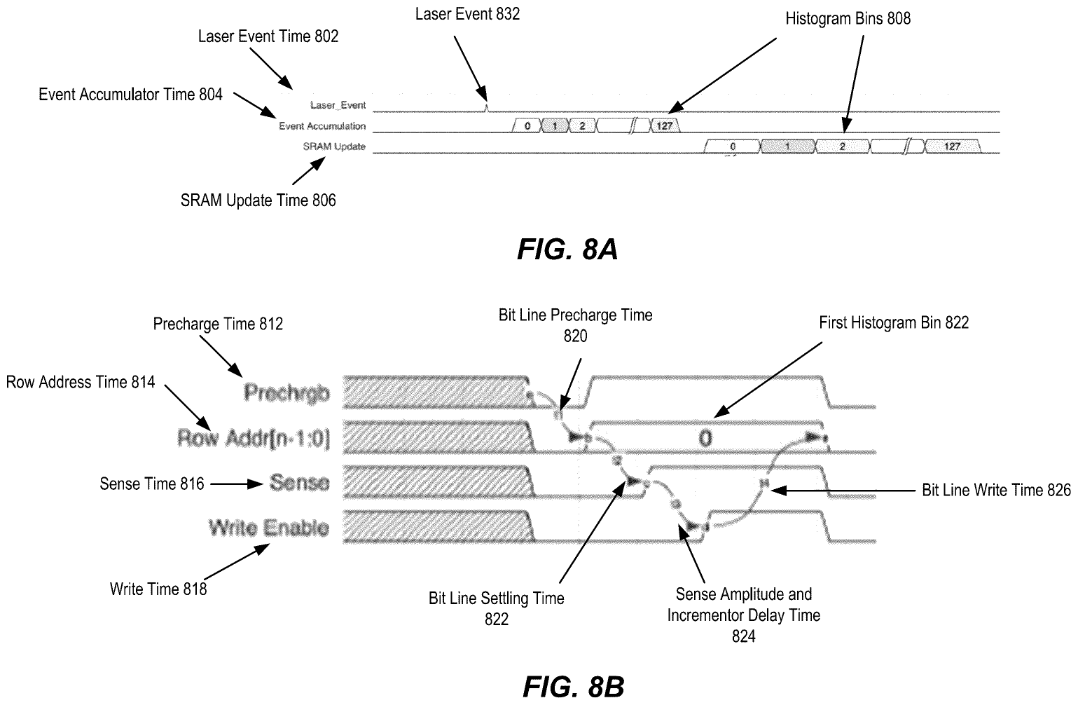

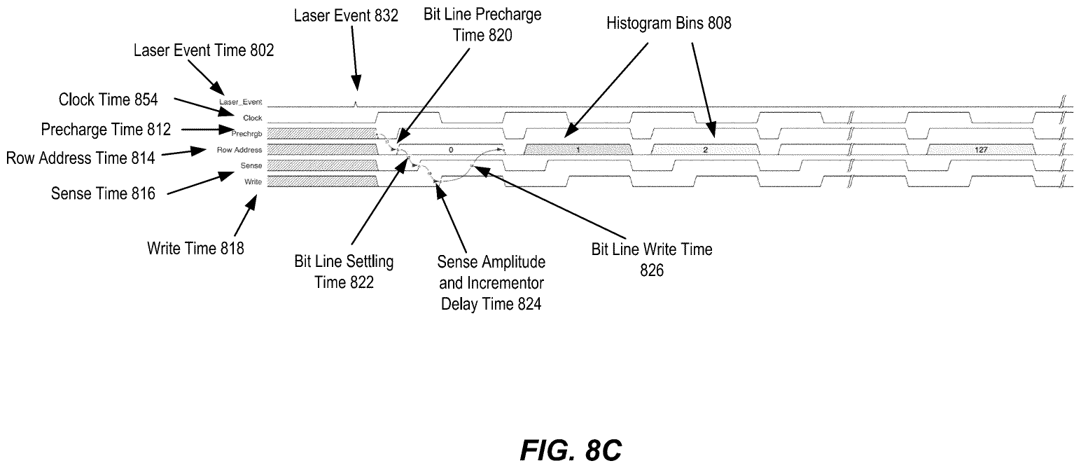

FIGS. 8A, 8B, and 8C illustrate example multiple time signals to capture a laser event. FIG. 8A shows the ROIC can include a plurality of bitlines and a plurality of controllers suitable to generate signals for a laser event time 802, an event accumulator time 804, and an SRAM update time 806 based on several threshold voltages of a transistor for a histogram on pixel DToF depth sensor with event register 328 when the SRAM pixel array is not fast enough to update SRAM values for a plurality of histogram bins 808 when a laser event 832 come in. Each of the plurality of bitlines is coupled to a corresponding one of the plurality of memory cells of the SRAM unit cell 310. The laser event time signal 802 can indicate the arrival time of a laser event 832. The event accumulator time signal 804 can indicate a first predetermined period, such as 10 ns for each histogram bin, based the laser event time signal 802 to count the occurrence of the photon associated with the detected laser event 832 using a 10 bit counter and a plurality of histogram bins 808. The SRAM update time signal 806 can indicate a second predetermined period, such as 30 ns for each histogram bin, based the event accumulator time signal 804 to update SRAM values associated with the plurality of histogram bins 808.

Furthermore, FIG. 8B shows four different time signals, such as a precharge time signal 812, a row address time signal 814, a sense time signal 816, and a write time signal 818, generated to update an SRAM value for the first histogram bin 822 of the plurality of histogram bins 808. The four digital signals can be used to start and stop a time measuring system to perform a particular operation during a time period. For example, the ROIC can precharge a bit line and/or a bit line bar to predetermined voltage levels prior to the start of a new cycle during the bit line precharge time 820 based on the precharge time signal 812 and the row address time signal 814. The ROIC can settle the predetermined voltage levels of the bit line and/or the bit line bar during the bit line settling time 822 based on the row address time signal 814 and the sense time signal 816. The ROIC can read and update an SRAM value associated with the first histogram bin 822 during the sense amplitude and incrementor delay time 824 based on the sense time signal 816 and the write time signal 818. The ROIC can write back the SRAM value associated with the first histogram bin 822 during the bit line write time 826 based on the write time signal 818 and the row address time signal 814.

Furthermore, FIG. 8C shows the ROIC can include a plurality of controllers suitable to generate signals for a laser event time signal 802, a clock time signal 854, a precharge time signal 812, a row address time signal 814, a sense time signal 816, and a write time signal 818 based on several threshold voltages of a transistor for a histogram on pixel DToF depth sensor without event register 328 when the SRAM pixel array is fast enough to update SRAM values for a plurality of histogram bins 808 in sequence as a laser event 832 comes in. The laser event time signal 802 can indicate the arrival time of a laser event 832. The clock time signal 854 can indicate a periodic pattern for a time interval generated from a global synchronous clock that re-times all of the input logic. In particular, the ROIC can precharge a bit line and/or a bit line bar to predetermined voltage levels prior to the start of a new cycle during the bit line precharge time 820 based on the precharge time signal 812 and the row address time signal 814. The ROIC can settle the predetermined voltage levels of the bit line and/or the bit line bar during the bit line settling time 822 based on the row address time signal 814 and the sense time signal 816. The ROIC can read and update an SRAM value associated with each of the plurality histogram bins 808 during the sense amplitude and incrementor delay time 824 based on the sense time signal 816 and the write time signal 818. The ROIC can write back the SRAM value associated each of the plurality histogram bins 808 during the bit line write time 826 based on the write time signal 818 and the row address time signal 814.

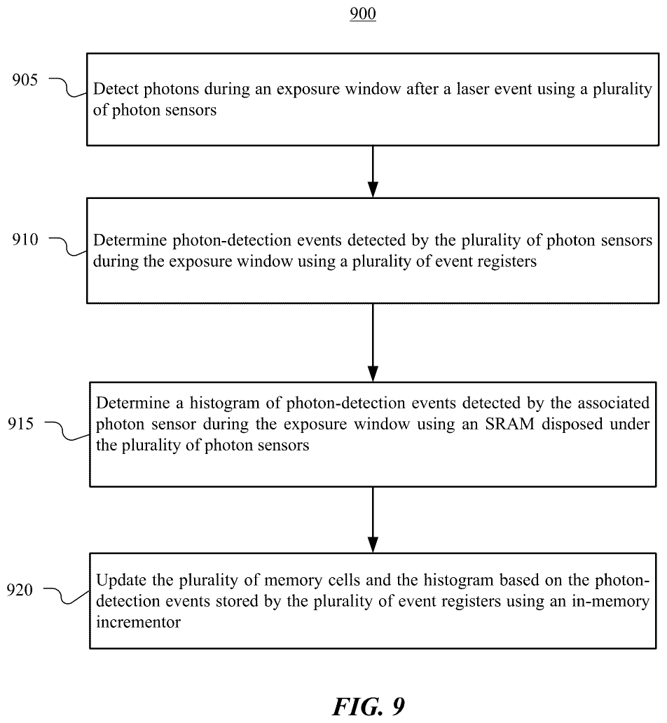

FIG. 9 illustrates an example method 900 for performing a method to generate a histogram of photon-detection events using a plurality of photon sensors. The method 900 may begin at step 905, where the system can obtain a plurality of photon sensors for detecting photons during an exposure window after a laser event. In particular embodiments, the plurality photon sensors can be embedded in a histogram on pixel DToF depth sensor. In particular embodiments, each of the plurality photon sensors can include a SPAD pixel array to detect photons during the exposure window after the laser event. At step 910, the system can determine photon-detection events detected by the plurality of photon sensors during the exposure window using a plurality of event registers. In particular embodiments, the system can use the plurality of event registers to count occurrence of the photon-detection events associated with the detected laser event using a 10 bit counter. At step 915, the system can determine a histogram of photon-detection events detected by the associated photon sensor during the exposure window using an SRAM disposed under the plurality of photon sensors. In particular embodiments, the plurality of memory cells is configured to store a histogram of photon-detection events detected by the associated photon sensor during the exposure window. In particular embodiments, cach memory cell of the plurality of memory cells is configured to store photon-detection events detected during a predetermined time period after the laser event. At step 920, the system can update the plurality of memory cells and the histogram based on the photon-detection events stored by the plurality of event registers using an in-memory incrementor. In particular embodiments, for each of the photon-detection events stored in the plurality of event registers, the in-memory incrementor is configured to read an event count stored in a selected one of the plurality of memory cells, increment the event count, and write the incremented event count back to the selected memory cell.

Particular embodiments may repeat one or more steps of the method of FIG. 9, where appropriate. Although this disclosure describes and illustrates particular steps of the method of FIG. 9 as occurring in a particular order, this disclosure contemplates any suitable steps of the method of FIG. 9 occurring in any suitable order. Moreover, although this disclosure describes and illustrates an example method for generating a histogram of photon-detection events using a plurality of photon sensors including the particular steps of the method of FIG. 9, this disclosure contemplates any suitable method for generating a histogram of photon-detection events using a plurality of photon sensors including any suitable steps, which may include all, some, or none of the steps of the method of FIG. 9, where appropriate. Furthermore, although this disclosure describes and illustrates particular components, devices, or systems carrying out particular steps of the method of FIG. 9, this disclosure contemplates any suitable combination of any suitable components, devices, or systems carrying out any suitable steps of the method of FIG. 9.

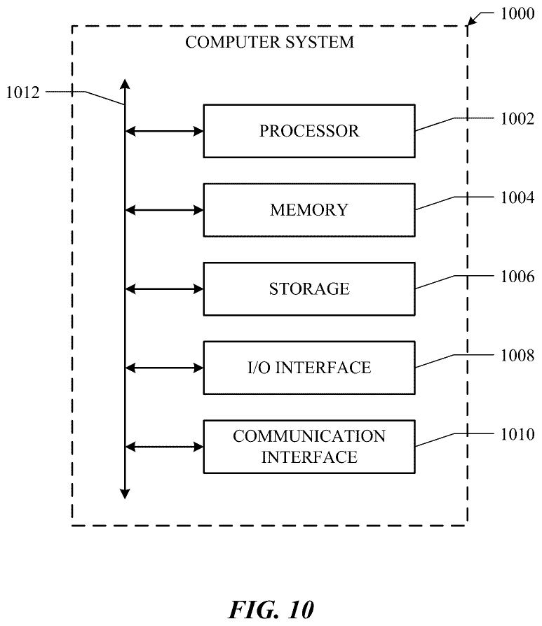

FIG. 10 illustrates an example computer system 1000. In particular embodiments, one or more computer systems 1000 perform one or more steps of one or more methods described or illustrated herein. In particular embodiments, one or more computer systems 1000 provide functionality described or illustrated herein. In particular embodiments, software running on one or more computer systems 1000 performs one or more steps of one or more methods described or illustrated herein or provides functionality described or illustrated herein. Particular embodiments include one or more portions of one or more computer systems 1000. Herein, reference to a computer system may encompass a computing device, and vice versa, where appropriate. Moreover, reference to a computer system may encompass one or more computer systems, where appropriate.

This disclosure contemplates any suitable number of computer systems 1000. This disclosure contemplates computer system 1000 taking any suitable physical form. As example and not by way of limitation, computer system 1000 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, computer system 1000 may include one or more computer systems 1000; be unitary or distributed; span multiple locations; span multiple machines; span multiple data centers; or reside in a cloud, which may include one or more cloud components in one or more networks. Where appropriate, one or more computer systems 1000 may perform without substantial spatial or temporal limitation one or more steps of one or more methods described or illustrated herein. As an example and not by way of limitation, one or more computer systems 1000 may perform in real time or in batch mode one or more steps of one or more methods described or illustrated herein. One or more computer systems 1000 may perform at different times or at different locations one or more steps of one or more methods described or illustrated herein, where appropriate.

In particular embodiments, computer system 1000 includes a processor 1002, memory 1004, storage 1006, an input/output (I/O) interface 1008, a communication interface 1010, and a bus 1012. Although this disclosure describes and illustrates a particular computer system having a particular number of particular components in a particular arrangement, this disclosure contemplates any suitable computer system having any suitable number of any suitable components in any suitable arrangement.

In particular embodiments, processor 1002 includes hardware for executing instructions, such as those making up a computer program. As an example and not by way of limitation, to execute instructions, processor 1002 may retrieve (or fetch) the instructions from an internal register, an internal cache, memory 1004, or storage 1006; decode and execute them; and then write one or more results to an internal register, an internal cache, memory 1004, or storage 1006. In particular embodiments, processor 1002 may include one or more internal caches for data, instructions, or addresses. This disclosure contemplates processor 1002 including any suitable number of any suitable internal caches, where appropriate. As an example and not by way of limitation, processor 1002 may include one or more instruction caches, one or more data caches, and one or more translation lookaside buffers (TLBs). Instructions in the instruction caches may be copies of instructions in memory 1004 or storage 1006, and the instruction caches may speed up retrieval of those instructions by processor 1002. Data in the data caches may be copies of data in memory 1004 or storage 1006 for instructions executing at processor 1002 to operate on; the results of previous instructions executed at processor 1002 for access by subsequent instructions executing at processor 1002 or for writing to memory 1004 or storage 1006; or other suitable data. The data caches may speed up read or write operations by processor 1002. The TLBs may speed up virtual-address translation for processor 1002. In particular embodiments, processor 1002 may include one or more internal registers for data, instructions, or addresses. This disclosure contemplates processor 1002 including any suitable number of any suitable internal registers, where appropriate. Where appropriate, processor 1002 may include one or more arithmetic logic units (ALUs); be a multi-core processor; or include one or more processors 1002. Although this disclosure describes and illustrates a particular processor, this disclosure contemplates any suitable processor.

In particular embodiments, memory 1004 includes main memory for storing instructions for processor 1002 to execute or data for processor 1002 to operate on. As an example and not by way of limitation, computer system 1000 may load instructions from storage 1006 or another source (such as, for example, another computer system 1000) to memory 1004. Processor 1002 may then load the instructions from memory 1004 to an internal register or internal cache. To execute the instructions, processor 1002 may retrieve the instructions from the internal register or internal cache and decode them. During or after execution of the instructions, processor 1002 may write one or more results (which may be intermediate or final results) to the internal register or internal cache. Processor 1002 may then write one or more of those results to memory 1004. In particular embodiments, processor 1002 executes only instructions in one or more internal registers or internal caches or in memory 1004 (as opposed to storage 1006 or elsewhere) and operates only on data in one or more internal registers or internal caches or in memory 1004 (as opposed to storage 1006 or elsewhere). One or more memory buses (which may each include an address bus and a data bus) may couple processor 1002 to memory 1004. Bus 1012 may include one or more memory buses, as described below. In particular embodiments, one or more memory management units (MMUs) reside between processor 1002 and memory 1004 and facilitate accesses to memory 1004 requested by processor 1002. In particular embodiments, memory 1004 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 1004 may include one or more memories 1004, where appropriate. Although this disclosure describes and illustrates particular memory, this disclosure contemplates any suitable memory.

In particular embodiments, storage 1006 includes mass storage for data or instructions. As an example and not by way of limitation, storage 1006 may include a hard disk drive (HDD), a floppy disk drive, flash memory, an optical disc, a magneto-optical disc, magnetic tape, or a Universal Serial Bus (USB) drive or a combination of two or more of these. Storage 1006 may include removable or non-removable (or fixed) media, where appropriate. Storage 1006 may be internal or external to computer system 1000, where appropriate. In particular embodiments, storage 1006 is non-volatile, solid-state memory. In particular embodiments, storage 1006 includes read-only memory (ROM). Where appropriate, this ROM may be mask-programmed ROM, programmable ROM (PROM), erasable PROM (EPROM), electrically crasable PROM (EEPROM), electrically alterable ROM (EAROM), or flash memory or a combination of two or more of these. This disclosure contemplates mass storage 1006 taking any suitable physical form. Storage 1006 may include one or more storage control units facilitating communication between processor 1002 and storage 1006, where appropriate. Where appropriate, storage 1006 may include one or more storages 1006. Although this disclosure describes and illustrates particular storage, this disclosure contemplates any suitable storage.

In particular embodiments, I/O interface 1008 includes hardware, software, or both, providing one or more interfaces for communication between computer system 1000 and one or more I/O devices. Computer system 1000 may include one or more of these I/O devices, where appropriate. One or more of these I/O devices may enable communication between a person and computer system 1000. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 1008 for them. Where appropriate, I/O interface 1008 may include one or more device or software drivers enabling processor 1002 to drive one or more of these I/O devices. I/O interface 1008 may include one or more I/O interfaces 1008, where appropriate. Although this disclosure describes and illustrates a particular I/O interface, this disclosure contemplates any suitable I/O interface.

In particular embodiments, communication interface 1010 includes hardware, software, or both providing one or more interfaces for communication (such as, for example, packet-based communication) between computer system 1000 and one or more other computer systems 1000 or one or more networks. As an example and not by way of limitation, communication interface 1010 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 1010 for it. As an example and not by way of limitation, computer system 1000 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 1000 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 1000 may include any suitable communication interface 1010 for any of these networks, where appropriate. Communication interface 1010 may include one or more communication interfaces 1010, where appropriate. Although this disclosure describes and illustrates a particular communication interface, this disclosure contemplates any suitable communication interface.

In particular embodiments, bus 1012 includes hardware, software, or both coupling components of computer system 1000 to each other. As an example and not by way of limitation, bus 1012 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 1012 may include one or more buses 1012, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A depth sensing system, comprising:
a plurality of photon sensors for detecting photons during an exposure window after a laser event;
a plurality of event registers configured to store photon-detection events detected by the plurality of photon sensors during the exposure window;
an SRAM disposed under the plurality of photon sensors, the SRAM comprising:
a plurality of memory cells associated with each photon sensor of the plurality of photon sensors, wherein the plurality of memory cells is configured to store a histogram of photon-detection events detected by the associated photon sensor during the exposure window, and each memory cell of the plurality of memory cells is configured to store photon-detection events detected during a predetermined time period after the laser event; and
an in-memory incrementor configured to update the plurality of memory cells based on the photon-detection events stored by the plurality of event registers, wherein for each of the photon-detection events stored in the plurality of event registers, the in-memory incrementor is configured to read an event count stored in a selected one of the plurality of memory cells, increment the event count, and write the incremented event count back to the selected memory cell.

2. The depth sensing system of claim 1, wherein the plurality of memory cells and the in-memory incrementor are coupled to a row decoder and a column decoder to decode a row address and a column address for each of the plurality of memory cells associated with each photon sensor of the plurality of photon sensors.

3. The depth sensing system of claim 1, wherein the SRAM disposed under the plurality of photon sensors comprises 128 memory cells associated with each photon sensor of the plurality of photon sensors.

4. The depth sensing system of claim 1, wherein a quenching transistor, an event synchronizer, and an OR tree are coupled to the plurality of memory cells to generate a plurality signals for laser event time, precharge time, row address time, sense time, and write time.

5. The depth sensing system of claim 4, wherein the SRAM disposed under the plurality of photon sensors further comprises:
a plurality of bitlines, each of the plurality of bitlines being coupled to a corresponding one of the plurality of memory cells;
a precharge circuit configured to determine a precharge time for the plurality of bitlines using the precharge time signal and the row address time signal;
a bit line settling circuit configured to determine a bit line settling time for the plurality of bitlines using the row address time signal and the sense time signal;
a sense amplitude and incrementor delay circuit configured to determine a sense amplitude and incrementor delay time for the plurality of bitlines using the sense time signal and the write time signal; and
a write delay circuit configured to determine a write delay time for the plurality of bitlines using the row address time signal and the write time signal.

6. The depth sensing system of claim 1, wherein the SRAM disposed under the plurality of photon sensors performs one or more operations on SRAM values for the plurality of memory cells using the event count stored in the plurality of memory cells.

7. The depth sensing system of claim 6, wherein the one or more operations include a read operation, a write operation, a fresh operation, and an update operation.

8. The depth sensing system of claim 6, wherein the one or more operations are performed using row/column address for each of the plurality of memory cells.

9. The depth sensing system of claim 1, wherein the SRAM disposed under the plurality of photon sensors determines a direct time to flight using a time to digital converter based on the histogram of photon-detection events detected by the associated photon sensor during the exposure window.

10. The depth sensing system of claim 1, wherein the SRAM disposed under the plurality of photon sensors is coupled to a global synchronous clock that re-times all input logic.

11. The method for detecting photons, comprising:
detecting photons during an exposure window after a laser event using a plurality of photon sensors;
determining photon-detection events detected by the plurality of photon sensors during the exposure window using a plurality of event registers;
determining a histogram of photon-detection events detected by the associated photon sensor during the exposure window using an SRAM disposed under the plurality of photon sensors, wherein the SRAM comprises a plurality of memory cells associated with each photon sensor of the plurality of photon sensors, and each memory cell of the plurality of memory cells is configured to store photon-detection events detected during a predetermined time period after the laser event; and
updating the plurality of memory cells and the histogram based on the photon-detection events stored by the plurality of event registers using an in-memory incrementor, wherein for each of the photon-detection events stored in the plurality of event registers, the in-memory incrementor is configured to read an event count stored in a selected one of the plurality of memory cells, increment the event count, and write the incremented event count back to the selected memory cell.

12. The method of claim 11, further comprising:
coupling the plurality of memory cells and the in-memory incrementor to a row decoder and a column decoder to decode a row address and a column address for each of the plurality of memory cells associated with each photon sensor of the plurality of photon sensors.

13. The method of claim 11, wherein the SRAM disposed under the plurality of photon sensors comprises 128 memory cells associated with each photon sensor of the plurality of photon sensors.

14. The method of claim 11, further comprising:
coupling a quenching transistor, an event synchronizer, and an OR tree to the plurality of memory cells to generate a plurality signals for laser event time, precharge time, row address time, sense time, and write time.

15. The method of claim 14, further comprising:
determining a precharge time for a plurality of bitlines using the precharge time signal and the row address time signal, wherein each of the plurality of bitlines is coupled to a corresponding one of the plurality of memory cells;
determining a bit line settling time for the plurality of bitlines using the row address time signal and the sense time signal;
determining a sense amplitude and incrementor delay time for the plurality of bitlines using the sense time signal and the write time signal; and
determining a write delay time for the plurality of bitlines using the row address time signal and the write time signal.

16. The method of claim 11, further comprising:
performing one or more operations on SRAM values for the plurality of memory cells using the event count stored in the plurality of memory cells, wherein the one or more operations include a read operation, a write operation, a fresh operation, and an update operation.

17. The method of claim 16, wherein the one or more operations are performed using row/column address for each of the plurality of memory cells.

18. The method of claim 11, further comprising:
determining a direct time to flight using a time to digital converter based on the histogram of photon-detection events detected by the associated photon sensor during the exposure window.

19. The method of claim 11, further comprising:
coupling the SRAM disposed under the plurality of photon sensors to a global synchronous clock that re-times all input logic.

20. One or more computer-readable non-transitory storage media embodying software that is operable when executed to:
detect photons during an exposure window after a laser event using a plurality of photon sensors;
determine photon-detection events detected by the plurality of photon sensors during the exposure window using a plurality of event registers;
determine a histogram of photon-detection events detected by the associated photon sensor during the exposure window using an SRAM disposed under the plurality of photon sensors, wherein the SRAM comprises a plurality of memory cells associated with each photon sensor of the plurality of photon sensors, and each memory cell of the plurality of memory cells is configured to store photon-detection events detected during a predetermined time period after the laser event; and
update the plurality of memory cells and the histogram based on the photon-detection events stored by the plurality of event registers using an in-memory incrementor, wherein for each of the photon-detection events stored in the plurality of event registers, the in-memory incrementor is configured to read an event count stored in a selected one of the plurality of memory cells, increment the event count, and write the incremented event count back to the selected memory cell.
